(19) United States
(12) Patent Application Publication
(10) Pub. No.: US 2018/0067898 A1
(43) Pub. Date: Mar. 8, 2018

(54) DEVICE AND METHOD FOR HANDLING SYMBOL RATE ESTIMATION AND INTERFERENCE

(71) Applicant: MStar Semiconductor, Inc., Hsinchu Hsien (TW)

(72) Inventor: Fang-Ming YANG, Hsinchu Hsien (TW)

(21) Appl. No.: 15/690,850

(22) Filed: Aug. 30, 2017

(30) Foreign Application Priority Data
Sep. 6, 2016 (TW) 105128733

(51) Int. Cl. G06F 17/11; H04L 25/02; G06F 17/14; H03H 17/02

(52) U.S. Cl. CPC G06F 17/11; H04L 25/024; H03H 17/0213; H03H 17/0219; G06F 17/142

(57) ABSTRACT

A communication device includes: a receiving circuit, receiving a plurality of time-domain signals; a transforming circuit, coupled to the receiving circuit, transforming the plurality of time-domain signals to a plurality of frequency-domain signals according to a time-frequency transform operation; a magnitude circuit, coupled to the transforming circuit, performing an absolute value operation on the plurality of frequency-domain signals to generate a plurality of output signals; and a selecting circuit, coupled to the magnitude circuit, selecting a maximum signal that satisfies a check condition from the plurality of output signals.

This application claims the benefit of Taiwan application Serial No. 105128733, filed Sep. 6, 2016, the subject matter of which is incorporated herein by reference.

### BACKGROUND OF THE INVENTION

### Field of the Invention

The invention relates in general to a device and method for a communication system, and more particularly to a device and method for handling symbol rate estimation and interference.

### Description of the Related Art

To evaluate system performance or to set the configuration of a receiver, a receiver frequently needs to accurately estimate a symbol rate. However, when a signal is transmitted through a channel, it is affected by channel effects, e.g., co-channel interference (CCI), in a way that the receiver may not be able to accurately estimate the symbol rate. Thus, system performance may be incorrectly evaluated or the configuration of the receiver may be incorrectly set.

Further, in order mitigate the influence of interference, the receiver needs to learn the frequency of interference to prevent or eliminate the interference. However, due to negative effects (e.g., noises), it is challenging for the receiver to accurately estimate the frequency of the interference.

Therefore, there is a need for a solution that accurately estimates the symbol rate and the frequency of interference in the presence of channel effects.

### SUMMARY OF THE INVENTION

The invention is directed to a device and method for handling symbol rate estimation. The device and method of the present invention are capable of obtaining an accurate symbol rate while power consumption and locking time are reduced, hence solving the above issues.

The present invention discloses a communication device. The communication device includes: a receiving circuit, receiving a first plurality of time-domain signals; a transforming circuit, coupled to the receiving circuit, transforming the first plurality of time-domain signals to a first plurality of frequency-domain signals according to a time-frequency transform operation; a magnitude circuit, coupled to the transforming circuit, performing an absolute value operation on the first plurality of frequency-domain signals to generate a first plurality of output signals; and a selecting circuit, coupled to the magnitude circuit, selecting a maximum signal that satisfies a check condition from the first plurality of output signals.

The present invention further discloses a method. The method includes: receiving a first plurality of time-domain signals by a receiving circuit; transforming the first plurality of time-domain signals to a first plurality of frequency-domain signals according to a time-frequency transform operation by a transforming circuit; performing an absolute value operation o the first plurality of frequency-domain signals to generate a first plurality of output signals by a magnitude circuit; and selecting a maximum signal that satisfies a check condition from the first plurality of output signals by a selecting circuit.

The above and other aspects of the invention will become better understood with regard to the following detailed description of the preferred but non-limiting embodiments. The following description is made with reference to the accompanying drawings.

### BRIEF DESCRIPTION OF THE DRAWINGS

FIG. 1 is a block diagram of a communication system according to an embodiment of the present invention;

FIG. 2 is a block diagram of an estimating module according to an embodiment of the present invention;

FIG. 3 is a block diagram of a communication device according to an embodiment of the present invention;

FIG. 4 is a block diagram of a communication device according to an embodiment of the present invention;

FIG. 5 is a schematic diagram of an operation of a communication device according to an embodiment of the present invention;

FIG. 6 is a flowchart of a process according to an embodiment of the present invention; and

FIG. 7 is a block diagram of an estimating circuit according to an embodiment of the present invention.

### DETAILED DESCRIPTION OF THE INVENTION

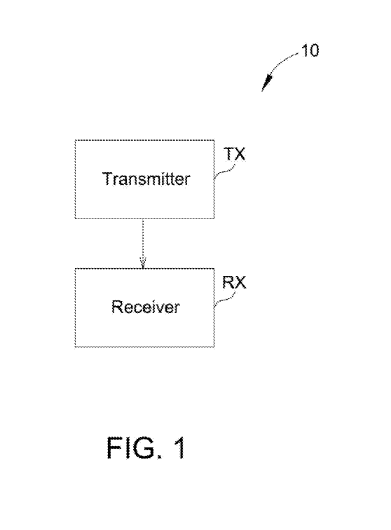

FIG. 1 shows a block diagram of a communication system 10 according to an embodiment of the present invention. The communication system 10 may be any communication system that transmits and/or receives single-carrier or multi-carrier signals, and is primarily formed by a transmitter TX and a receiver RX. For example but not limited to, the multi-carrier signal may be an orthogonal frequency-division multiplexing (OFDM) signal (or referred to as a discrete multi-tone modulation (DMT) signal). In FIG. 1, the transmitter TX and the receiver RX are for illustrating the architecture of the communication system 10. For example, the communication system 10 may be wired communication system such as an asymmetric digital subscriber line (ADSL) system, a power line communication (PLC) system or an Ethernet over coax (EOC) system, or a wireless communication system such as a wireless local area network (WLAN), a Digital Video Broadcasting (DVB) system or a Long Term Evolution-Advanced (LTE-A) system. The DVB system may include a Digital Terrestrial Multimedia Broadcast (DTMB) system, a DVB-Terrestrial (DVT-T) system, a DVB Terrestrial/Cable Second Generation (DVB-T2/C2) system and an Integrated Services Digital Broadcasting (ISDB) system. Further, for example but not limited to, the transmitter TX and the receiver RX may be disposed in a mobile phone, a laptop computer, a tablet computer, an e-book or a portable computer system.

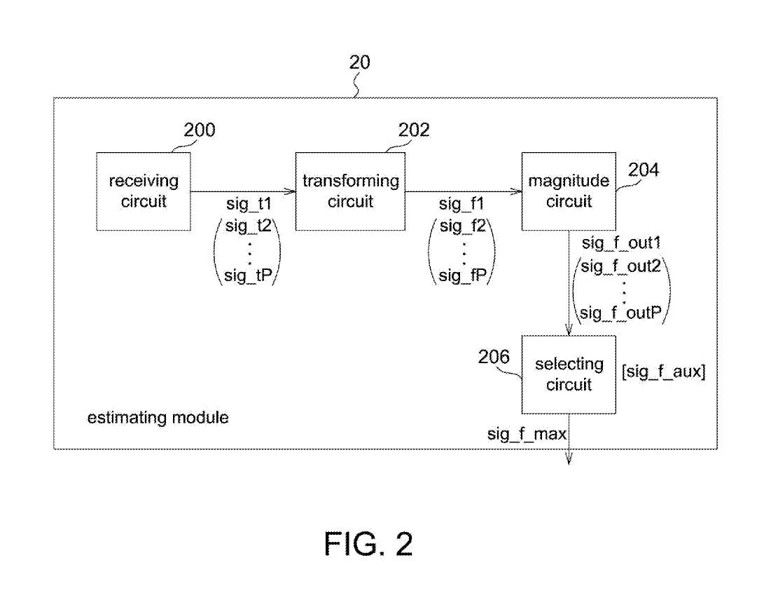

FIG. 2 shows a block diagram of an estimating module 20 according to an embodiment of the present invention. The estimating module 20 is applied in the receiver RX in FIG. 1, and may be used to estimate the bandwidth of a received signal or a frequency of interference. The estimating module 20 includes a receiving circuit 200, a transforming circuit 202, a magnitude circuit 204 and a selecting circuit 206. More specifically, after receiving a plurality of time-domain signals sig_t1, the receiving circuit 200 provides the time-domain signals sig_t1 to the transforming circuit 202. The time-domain signals sig_t1 may be, for example but not limited to, signals generated through performing 16 quadrature amplitude modulation (QAM), 32QAM, 64QAM, 128QAM or 256QAM operations. The transforming circuit 202, coupled to the channel estimating circuit 200, transforms the time-domain signals sig_t1 to a plurality of frequency-domain signals sig_f1 according to a time-frequency transform operation. For example but not limited to, the time-frequency transform operation may be an algorithm such as fast Fourier transform (FFT) that transforms time-domain signals to frequency-domain signals. The magnitude circuit 204 performs an absolute value operation (i.e., that obtains respective absolute values of the frequency-domain signals sig_f1) on the frequency-domain signals sig_f1 to generate a plurality of output signals sif_f_out1.

The receiving circuit 200 may further receive a plurality of time-domain signals sig_t2. Similarly, the transforming circuit 202 transforms the time-domain signals sig_t2 to a plurality of frequency-domain signals sig_f2 according to the time-frequency transform operation. The magnitude circuit 204 performs the absolute value operation (i.e., that obtains respective absolute values of the frequency-domain signals sig_f2) on the frequency-domain signals sig_f2 to generate a plurality of output signals sig_f_out2. The selecting circuit 206 may correspondingly add the output signals sig_f_out1 and the output signals sig_f_out2 to generate a plurality of auxiliary signals sig_f_aux. The above operation may be repeated for a predetermined number of times, i.e., superimposing the output signals to the predetermined number of times.

The selecting circuit 206 selects a maximum signal sig_f_max that satisfies a check condition from the auxiliary signals sig_f_aux (or from the output signals sig_f_out1 if superimposing is not performed). The maximum signal sig_f_max has a maximum amplitude that satisfies the check condition. Based on the above description, during the process of searching for the maximum signal, the selecting circuit 206 considers not only the magnitude of the amplitude but also whether the signal satisfies the check condition. Thus, through the check condition, negative effects (e.g., noises and/or interference) may be reduced to increase the reliability of the selected signal.

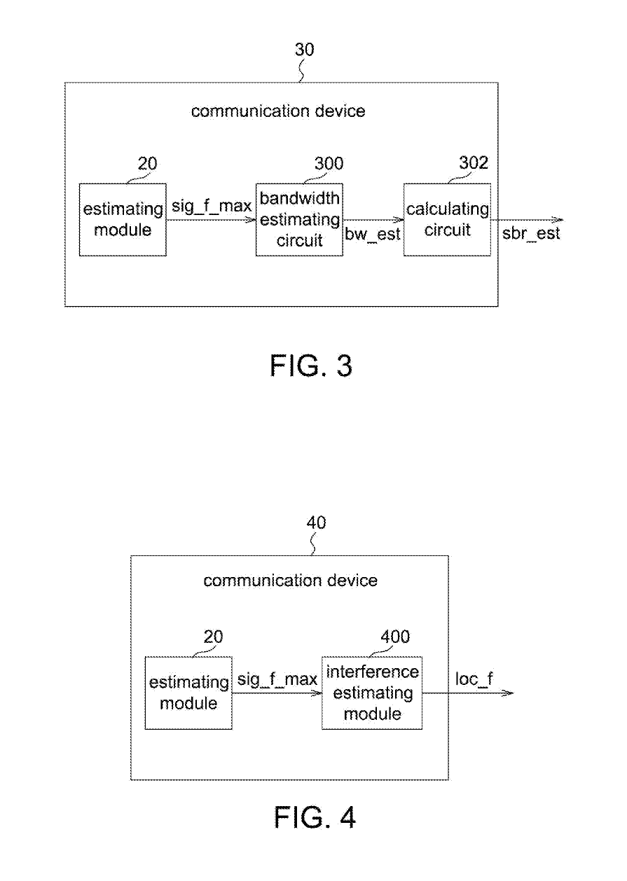

FIG. 3 shows a block diagram of a communication device 30 according to an embodiment of the present invention. The communication device 30 is applied in the receiver RX in FIG. 1, and is used to estimate a symbol rate of a received signal. The communication device 30 includes an estimating module 20, a bandwidth estimating circuit 300 and a calculating circuit 302. The bandwidth estimating circuit 300, coupled to the estimating module 20, estimates a bandwidth bw_est according to the maximum signal sig_f_max and a minimum output signal sig_f_min among the auxiliary signals sig_f_aux (or from the output signals sig_f_out1 if superimposing is not performed). Because the selected maximum signal sig_f_out has higher reliability, the accuracy of the bandwidth bw_est may be increased. The calculating circuit 302, coupled to the bandwidth estimating circuit 300, calculates a symbol rate sbr_est according to the bandwidth bw_est. As previously stated, because the bandwidth bw_est has a higher accuracy, the bit rate sbr_est obtained according to the bandwidth bw_est correspondingly has a higher accuracy, such that the receiver RX may accurately estimate the system performance or set the configuration of the receiver RX according to the symbol rate sbr_est. Based on the definition of the symbol rate sbr_est, different corresponding relationships exist between the bandwidth bw_est and the symbol rate sbr_est. For example, when the bandwidth bw_est and the symbol rate sbr_est are equal (or similar), the calculating circuit 300 may directly output the bandwidth bw_est as the symbol rate sbr_est. At this point, the bandwidth estimating circuit 300 and the calculating circuit 302 may be integrated as one single circuit. When the bandwidth bw_est differs from the symbol rate sbr_est significantly, one person skilled in the art may correspondingly design or modify the calculating circuit 300 to obtain the defined symbol rate.

FIG. 4 shows a block diagram of a communication device 40 according to an embodiment of the present invention. The communication device 40 is applied in the receiver RX in FIG. 1, and is used for determining a position of a frequency of interference. The communication device 40 includes an estimating module 20 and an interference estimating circuit 400. The interference estimating module 400, coupled to the estimating module 20, determines a frequency loc_f of the maximum signal. Because the selected maximum signal sig_max has higher reliability, the accuracy of the frequency loc_f may also be increased.

It should be noted that, there are numerous ways for the selecting circuit 206 to select the maximum signal. For example, the selecting circuit 206 selects the maximum signal that satisfies the check condition sequentially from the output signals sig_f_out1 (or from the auxiliary signals sig_f_aux if superimposed is performed) by means of a window according to a sliding window method. Further, there are also numerous ways for implementing the check condition used for determining the reliability of a signal.

In one embodiment, when the selecting circuit 206 is used to estimate the bandwidth, one of the plurality of sets of output signals may satisfy the check condition according to an equation:

f({Zₖ}_{k=1,k≠sub}_{_}ₘₐₓ^{M})+Z_{sub}_{_}ₘₐₓ>G*Z_{sub}_{_}ₘₐₓ (1)

In equation (1), {Zₖ}ₖ₌₁^{M} is the set of output signals, M is a size of the window, f(•) is a function, sub_max is an index of a maximum signal of the set of output signals, and G is a positive real number. Preferably, G is a gain margin. That is to say, the check condition is determined as satisfied when G*Z_{sub}_{_}ₘₐₓ is not excessively large. G is a designed value or a predetermined value, and may be determined based on system considerations or design requirements. For example, when higher reliability is required, G may be set to a larger positive real number, i.e., the maximum signal G*Z_{sub}_{_}ₘₐₓ less likely satisfies equation (1). Conversely, when lower reliability is required, G may be set to a smaller positive real number, i.e., the maximum signal G*Z_{sub}_{_}ₘₐₓ more easily satisfies equation (1).

In another embodiment, when the selecting circuit 206 is used for estimating interference, one of the plurality of sets of output signals may satisfy the check condition according to an equation:

f({Zₖ}_{k=1,k≠sub}_{_}ₘₐₓ^{M})+Z_{sub}_{_}ₘₐₓ <G*Z_{sub}_{_}ₘₐₓ (2)

In equation (2), {Zₖ}ₖ₌₁^{M} is the set of output signals, M is a size of the window, f(•) is a function, sub_max is an index of a maximum signal of the set of output signals, and G is a positive real number. Preferably, G is a gain margin. That is to say, the check condition is determined as satisfied when G*Z_{sub}_{_}ₘₐₓ is sufficiently large. G is a designed value or a predetermined value, and may be determined based on system considerations or design requirements. For example, when higher reliability is required, G may be set to a smaller positive real number, i.e., the maximum signal G*Z_{sub}_{_}ₘₐₓ less likely satisfies equation (2). Conversely, when lower reliability is required, G may be set to a larger positive real number, i.e., the maximum signal G*Z_{sub}_{_}ₘₐₓ more easily satisfies equation (2).

It should be noted that, in the above embodiment, the functions of equation (1) and equation (2) may be an equation:

f({Zₖ}_{k=1,k ≠sub}_{_}ₘₐₓ^{M})=Σ_{k=1,k≠sub}_{_}ₘₐₓ^{M}Zₖ (3)

That is, equation (1) and equation (2) mean that G*Z_{sub}_{_}ₘₐₓ needs to be greater than the sum of all {Zₖ}ₖ₌₁^{M} in order to be determined that the check condition is satisfied. Further, equation (1) to equation (3) illustrate a method in which the maximum signal is selected from one set of output signals, and the selecting circuit 206 repeatedly performs equation (1) to equation (3) on all of the sets of output signals of the plurality of outputs signals sig_f_out1 (or the plurality of auxiliary signals sig_f_aux obtained after superimposing) to select the maximum signal sig_f_max.

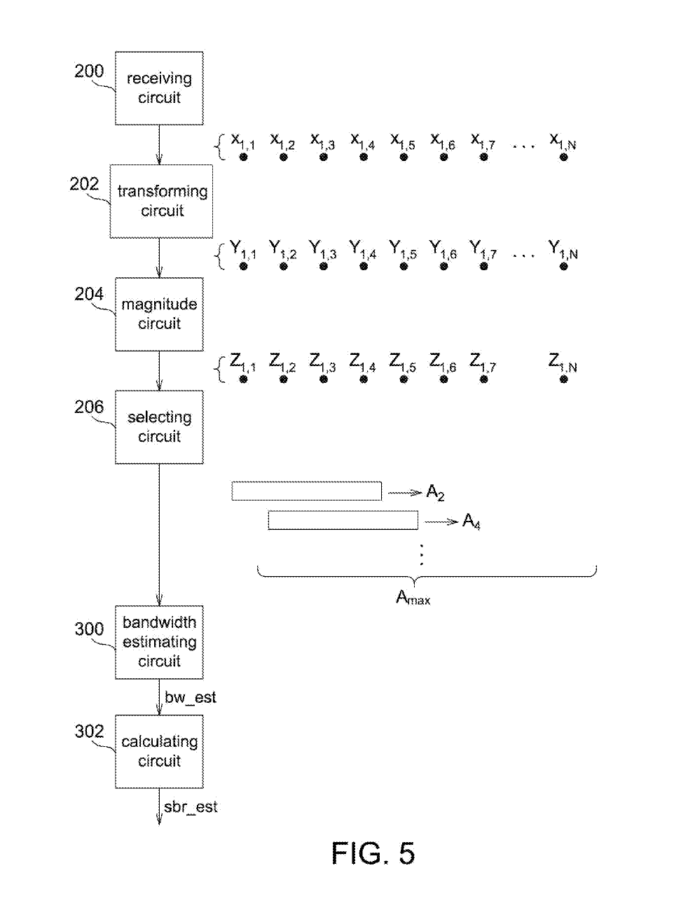

FIG. 5 shows a schematic diagram of an operation of a communication device 30 according to an embodiment of the present invention for explaining operation details of the communication device 30. In FIG. 5, the receiving circuit 200 receives a plurality of time-domain signals sig_t1 (x_{1,1}, . . . , x_{1,N}), where N is the size of FFT. The transforming circuit 202 transforms the time-domain signals sig_t1 (x_{1,1}, . . . , x_{1,N}) to a plurality of frequency-domain signals sig_f1 (Y_{1,1}, . . . , Y_{1,N}) according to a time-frequency transform operation. The magnitude circuit 204 performs an absolute value operation on the frequency-domain signals sig_f1 (Y_{1,1}, . . . , Y_{1,N}) to generate a plurality of output signals sig_f_out1 (Z_{1,1}, . . . , Z_{1,N}); i.e., Z_{1,k}=|Y_{1,k}|, k=1, . . . , N. The communication device 30 may perform superimposing according to a user-defined condition, with associated details given below. The receiver 200 continues receiving a plurality of time-domain signals sig_t2 (x_{2,1}, . . . , x_{2,N}). The transforming circuit 202 transforms the time-domain signals sig_t2 (x_{2,1}, . . . , x_{2,N}) to a plurality of frequency-domain signals sig_f2 (Y_{2,1}, . . . , Y_{2,N}) according to the time-frequency transform operation. The magnitude circuit 204 performs the absolute value operation on the frequency-domain signals sig_f2 (Y_{2,1}, . . . , Y_{2,N}) to generate a plurality of outputs signals sig_f_out 2 (Z_{2,1}, . . . , Z_{2,N}); i.e., Z_{2,k}=|Y_{2,k}|, k=1, . . . , N. The selecting circuit 206 correspondingly adds the output signals sig_f_out1 (Z_{1,1}, . . . , Z_{1,N}) and the output signals sig_f_out 2 (Z₂, . . . , Z_{2,N}) to generate a plurality of auxiliary signals sig_f_aux (A₁, . . . , A_{N}); i.e., Aₖ=Σₙ₌₁²Z_{n,k}. The selecting circuit 206 selects a plurality of maximum signals sig_f_max that satisfy the check condition sequentially from the auxiliary signals sig_f_aux (A₁, . . . , A_{N}) by means of a window according to a sliding window method. To clearly explain the embodiment to better understand the concept of the present invention, it is assumed that the check conditions are equation (1) and equation (3) in the embodiment.

For example, the size of the window that the selecting circuit 206 uses is 4 (i.e., M=4 in equation (1)), and a maximum signal is first selected from the auxiliary signals A₁, . . . , A₄, e.g., the auxiliary signal A₂. Next, the selecting circuit 206 checks whether A₂ satisfies Σ_{k=1,k≠2}⁴Aₖ+A₂>G*A₂. As previously described, G is a positive real number and may be determined based on system considerations and design requirements. When the auxiliary signal A₂ satisfies the check condition, the selecting circuit 206 regards the auxiliary signal A₂ as the maximum signal for estimating a valid bandwidth, and stores the auxiliary signal A₂ to the estimating module 20. According to the sliding window method, the selecting circuit 206 continues selecting a maximum signal from the auxiliary signals A₂, . . . , A₅, e.g., the auxiliary signal A₄, and compares the size of the selected auxiliary signal with that of the previously stored auxiliary signal A₂. Next, the selecting circuit 206 checks whether the auxiliary signal A₄ satisfies the condition A₄>A₂. When this condition is satisfied, the temporarily stored maximum signal is updated as the auxiliary signal A₄. It is continued to check Σ_{k=2,k≠4}⁵Aₖ+A₄>G*A₄. If the auxiliary signal A₄ satisfies the check condition, the bandwidth estimated according to this maximum value is determined as being valid. If auxiliary signal A₄ does not satisfy the check condition, the bandwidth estimated according to this maximum value is determined as being invalid. Furthermore, if A₄>A₂ is not satisfied, the auxiliary signal A₂ remains as the maximum signal and a state of regarding the bandwidth estimated according to the auxiliary signal A₂ as being valid or invalid is maintained. The selecting circuit 206 continues performing the above operation until the auxiliary signals A_{N-3}, . . . , A_{N} have all been processed.

After the above operation is performed, it is determined that the bandwidth estimated according to the maximum signal, e.g., the auxiliary signal Aₘₐₓ, is valid if the maximum signal satisfies the check condition. Thus, the bandwidth estimating circuit 300 may estimate the bandwidth bw_est according to the output signal Aₘₐₓ, and the calculating circuit 302 may calculate the symbol rate sbr_est according to the bandwidth bw_est.

Operation details of the communication device 30 are similar to those of the communication device 20, with one main difference being that, the bandwidth estimating circuit 300 and the calculating circuit 302 are replaced by the interference estimating circuit 400. For example, operations associated with equation (1) and equation (3) are replaced by operations associated with equation (2) and equation (3)—such repeated description is omitted herein.

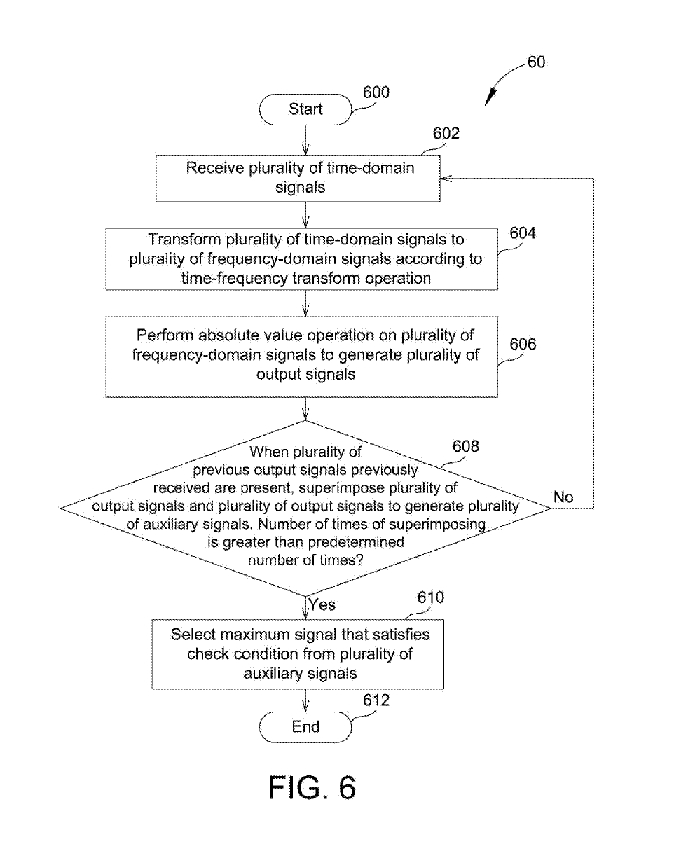

The operation of the estimating module 20 may be concluded into a process 60 according to an embodiment of the present invention based on the foregoing embodiments. The process 60 is applied in the communication device 30 or the communication device 40, and includes following steps, as shown in FIG. 6.

In step 600, the process 60 begins.

In step 602, a plurality of time-domain signals are received.

In step 604, the time-domain signals are transformed to a plurality of frequency-domain signals according to a time-frequency transform operation.

In step 606, an absolute value operation is performed on the frequency-domain signals to generate a plurality of output signals.

In step 608, if a plurality of previous output signals that are previously received are present, the output signals and the previous output signals are superimposed to generate a plurality of auxiliary signals. Step 610 is performed if the number of times of superimposing is equal to a predetermined number of times, otherwise step 602 is iterated.

In step 610, a maximum signal that satisfies a check condition is selected from the auxiliary signals.

In step 612, the process 60 ends.

The process 60 is an example for illustrating the operation of the estimating module 20, and associated details may be referred from the foregoing description and shall be omitted herein.

It should be noted that, there are numerous ways to realize the estimating module 20 (and the receiving circuit 200, the transforming circuit 202, the magnitude circuit 204 and the selecting circuit 206 included), the communication device 30 (and the estimating module 20, the bandwidth estimating circuit 300 and the calculating circuit 302 included) and the communication device 40 (and the estimating module 20 and the interference estimating circuit 40 included). For example, based on design considerations or system requirements, the above circuits are integrated into one or multiple circuits, and are usually implemented by a digital circuit/digital circuits. In one embodiment, the receiving circuit 200 may include an analog-to-digital converter (ADC). Further, the estimating module 20, the communication device 30 and the communication device 40 may be realized by hardware, software, firmware (a combination of a hardware device, computer instructions and data, with the computer instructions and data being read-only software in the hardware device), an electronic system, and/or a combination of the above devices.

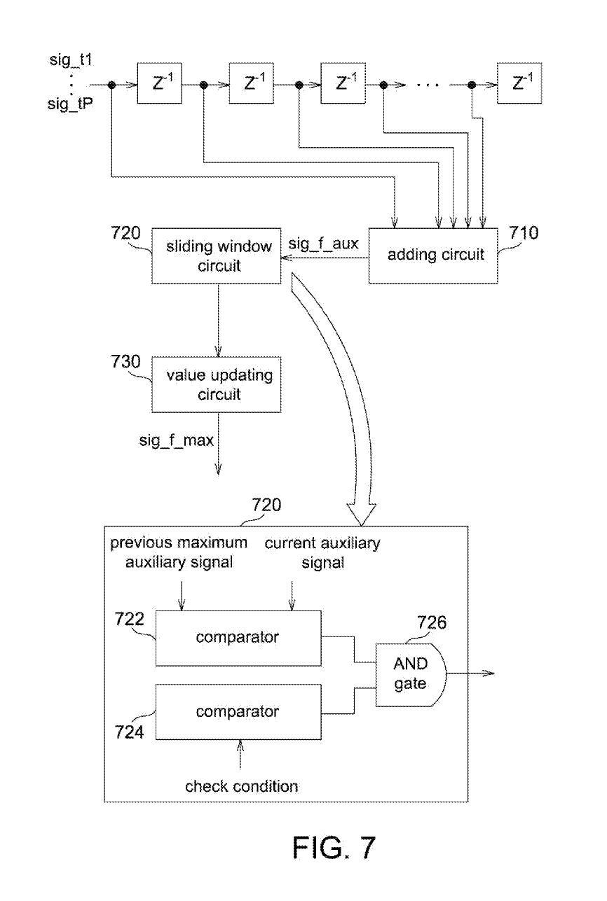

FIG. 7 shows a block diagram of an estimating circuit 70 according to an embodiment of the present invention. The estimating circuit 70 is used to realize the estimating module 20, and includes a plurality of registers 700, an adding circuit 710, a sliding window circuit 720 and a value updating circuit 730. More specifically, the registers 710 may receive a plurality of sets of time-domain signals sig_t1 to sig_tP, and sequentially output a plurality of sets of time-domain signals sig_t1 to sig_tP. The adding circuit 710, coupled to the registers 700, superimposes the sets of time-domain signals sig_t1 to sig_tP to obtain a plurality of auxiliary signals sig_f_aux. The sliding window circuit 720, coupled to the adding circuit 710, sequentially selects a maximum signal (e.g., A₂ and A₄ in the foregoing embodiment) that satisfies the check condition from the auxiliary signals sig_f_aux. The value updating circuit 730, coupled to the sliding window circuit 720, receives and compares the maximum signal outputted from the sliding window circuit 720. When the maximum signal received (e.g., A₄ in the foregoing embodiment) is greater than the current maximum signal (A₂ in the foregoing embodiment), the value updating circuit 730 replaces the current maximum signal by the received signal. Conversely, when the received maximum signal is smaller than the current maximum signal, the value updating circuit 730 preserves the current maximum signal. After the estimating circuit 70 finishes processing the received signals, the value updating circuit 730 may obtain the maximum signal sig_f_max (e.g., Aₘₐₓ in the foregoing embodiment).

In one embodiment, the sliding window circuit may include a comparator 722, a comparator 724 and an AND gate 726. More specifically, the comparator 722 may compare a set of auxiliary signals (e.g., A₁, . . . , A₄ in the foregoing embodiment) to obtain the maximum signal (A₂) in that set of auxiliary signals. The comparator 724 checks whether the maximum signal satisfies the check condition (e.g., equation (1) or equation (2) in the foregoing embodiment). The AND gate 726, coupled to the comparator 722 and the comparator 724, outputs the maximum signal to the value updating circuit 730 given that the maximum signal satisfies the check condition.

In conclusion, the present invention provides a device and method for handling symbol rate estimation and interference. The device and method of the present invention stop or continue receiving and handling additional time-domain signals according to whether a (maximum) signal satisfies a check condition. Thus, not only an accurate symbol rate and an accurate frequency of interference are obtained, but also unnecessary power consumption and lock time are reduced, thereby solving the issue that a communication device is required to process an excessive amount and unnecessary time-domain signals.

While the invention has been described by way of example and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A communication device, comprising:
a receiving circuit, receiving a first plurality of time-domain signals;
a transforming circuit, coupled to the receiving circuit, transforming the first plurality of time-domain signals to a first plurality of frequency-domain signals according to a time-frequency transform operation;
a magnitude circuit, coupled to the magnitude circuit, performing an absolute value operation on the first plurality of frequency-domain signals to generate a first plurality of output signals; and
a selecting circuit, coupled to the magnitude circuit, selecting a maximum signal that satisfies a check condition from the first plurality of output signals.

2. The communication device according to claim 1, further comprising:
a bandwidth selecting circuit, coupled to the selecting circuit, estimating a bandwidth according to the maximum signal and a minimum output signal among the first plurality of output signals; and
a calculating circuit, coupled to the bandwidth estimating circuit, calculating a symbol rate according to the bandwidth.

3. The communication device according to claim 1, further comprising:
an interference estimating circuit, coupled to the selecting circuit, determining a position of a frequency of the maximum signal.

4. The communication device according to claim 1, wherein when the first plurality of output signals do not comprise the maximum signal that satisfies the check condition, the communication device performs operations of:
receiving a second plurality of time-domain signals by the receiving circuit;
transforming the second plurality of time-domain signals to a second plurality of frequency-domain signals according to the time-frequency transform operation by the transforming circuit;
performing the absolute value operation on the second plurality of frequency-domain signals to generate a second plurality of output signals by the magnitude circuit; and
correspondingly adding the first plurality of output signals and the second plurality of output signals to generate a plurality of auxiliary signals, selecting the maximum signal from the plurality of auxiliary signals, and determining whether the maximum signal satisfies the check condition by the selecting circuit.

5. The communication device according to claim 1, wherein the selecting circuit selects the maximum signal sequentially from a plurality of sets of output signals of the first plurality of output signals by means of a window according to a sliding window method, and checks whether the maximum signal satisfies the check condition.

6. The communication device according to claim 5, wherein one set of the plurality of sets of output signals satisfies the check condition according to an equation:
f({Zₖ}_{k=1,k≠sub}_{_}ₘₐₓ^{M})+Z_{sub}_{_}max>G*Z_{sub}_{_}ₘₐₓ;
wherein, {Zₖ}ₖ₌₁^{M} is the set of output signals, M is a size of the window, f(•) is a function, sub_max is an index of a maximum signal of the set of output signals, and G is a positive real number.

7. The communication device according to claim 6, wherein the function is an equation:
f({Zₖ}_{k=1,k≠sub}_{_}ₘₐₓ^{M})=Σ_{k=1,k≠sub}_{_}ₘₐₓ^{M}Zₖ.

8. The communication device according to claim 5, wherein one set of the plurality of sets of output signals satisfies the check condition according to an equation:
f({Zₖ}_{k=1,k≠sub}_{_}ₘₐₓ^{M})+Z_{sub}_{_}ₘₐₓ<G*Z_{sub}_{_}ₘₐₓ;
wherein, {Zₖ}ₖ₌₁^{M} is the set of output signals, M is a size of the window, f(•) is a function, sub_max is an index of a maximum signal of the set of output signals, and G is a positive real number.

9. The communication device according to claim 1, wherein the time-frequency transform operation comprises a fast Fourier transform (FFT).

10. The communication device according to claim 1, wherein the maximum signal has a maximum amplitude that satisfies the check condition.

11. A method for handling bandwidth estimation, comprising:
receiving a first plurality of time-domain signals by a receiving circuit;
transforming the first plurality of time-domain signals to a first plurality of frequency-domain signals according to a time-frequency transform operation by a transforming circuit;
performing an absolute value operation on the first plurality of frequency-domain signals to generate a first plurality of output signals by a magnitude circuit; and
selecting a maximum signal that satisfies a check condition from the first plurality of output signals by a selecting circuit.

12. The method according to claim 11, further comprising:
estimating a bandwidth according to the maximum signal and a minimum output signal among the first plurality of output signals by a bandwidth estimating circuit; and
calculating a symbol rate according to the bandwidth by a calculating circuit.

13. The method according to claim 11, further comprising:
determining a position of a frequency of the maximum signal by an interference estimating circuit.

14. The method according to claim 11, wherein when the first plurality of output signals do not comprise the maximum signal that satisfies the check condition, the method further comprises:
receiving a second plurality of time-domain signals by the receiving circuit;
transforming the second plurality of time-domain signals to a second plurality of frequency-domain signals according to the time-frequency transform operation by the transforming circuit;
performing the absolute value operation on the second plurality of frequency-domain signals to generate a second plurality of output signals by the magnitude circuit; and
correspondingly adding the first plurality of output signals and the second plurality of output signals to generate a plurality of auxiliary signals, selecting the maximum signal from the plurality of auxiliary signals, and determining whether the maximum signal satisfies the check condition by the selecting circuit.

15. The method according to claim 11, further comprising:
selecting the maximum signal sequentially from a plurality of sets of output signals of the first plurality of output signals by means of a window according to a sliding window method, and checking whether the maximum signal satisfies the check condition by the selecting circuit.

16. The method according to claim 15, wherein one set of the plurality of sets of output signals satisfies the check condition according to an equation:
f({Zₖ}_{k=1,k≠sub}_{_}ₘₐₓ^{M})+Z_{sub}_{_}ₘₐₓ>G*Z_{sub}_{_}ₘₐₓ;
wherein, {Zₖ}ₖ₌₁^{M} is the set of output signals, M is a size of the window, f(•) is a function, sub_max is an index of a maximum signal of the set of output signals, and G is a positive real number.

17. The method according to claim 16, wherein the function is an equation:
f({Zₖ}_{k=1,k≠sub}_{_}ₘₐₓ^{M})=Σ_{k=1,k≠sub}_{_}ₘₐₓ^{M}Zₖ.

18. The method according to claim 15, wherein one set of the plurality of sets of output signals satisfies the check condition according to an equation:
f({Zₖ}_{k=1,k≠sub}_{_}ₘₐₓ^{M})+Z_{sub}_{_}ₘₐₓ<G*Z_{sub}_{_}ₘₐₓ;
wherein, {Zₖ}ₖ₌₁^{M} is the set of output signals, M is a size of the window, f(•) is a function, sub_max is an index of a maximum signal of the set of output signals, and G is a positive real number.

19. The method according to claim 11, wherein the time-frequency transform operation comprises a fast Fourier transform (FFT).

20. The method according to claim 11, wherein the maximum signal has a maximum amplitude that satisfies the check condition.
